(19) United States
(12) Patent Application Publication
(10) Pub. No.: US 2007/0090480 A1
(43) Pub. Date: Apr. 26, 2007

(54) Solid-state imaging device and method for manufacturing the same

(75) Inventor: Toshihiro Kuriyama, Shiga (JP)

Correspondence Address: HAMRE, SCHUMANN, MUELLER & LARSON P.C., P.O. BOX 2902-0902, MINNEAPOLIS, MN, 55402, US

(73) Assignee: MATSUSHITA ELECTRIC INDUSTRIAL CO., LTD., Kadoma-shi (JP)

(21) Appl. No.: 11/474,654

(22) Filed: Jun. 26, 2006

(30) Foreign Application Priority Data
Oct. 20, 2005 (JP) JP2005-306150

(51) Int. Cl. H01L 31/00

(52) U.S. Cl. 257/443; 257/E31.031

(57) ABSTRACT

The solid-state imaging device of the present invention includes: a plurality of photodetectors that are arranged in a two-dimensional matrix; a plurality of vertical transfer portions that transfer, in a vertical direction, signal electric charges which are read out from the respective photodetectors; a horizontal transfer portion that receives the signal electric charges transferred by the vertical transfer portions, and transfers the signal electric charges in a horizontal direction; a barrier region that is adjacent to the horizontal transfer portion, and allows an excess electric charge in the horizontal transfer portion to pass through; and a drain region that is adjacent to the barrier region and drains the excess electric charge which has passed through the barrier region; and bus lines that are disposed in parallel with the drain region, and apply control voltages to electrodes of the horizontal transfer portion. The bus lines and the electrodes of the horizontal transfer portion are connected via a connection pattern that is disposed between the bus lines and the drain region. A power loss in the horizontal transfer portion is suppressed, and both of an increase in the number of pixels and a decrease in power consumption are achieved.

### BACKGROUND OF THE INVENTION

1. Field of the Invention

The present invention relates to a solid-state imaging device and a method for manufacturing the same, and particularly relates to a CCD (charge coupled device) solid-state imaging device and a method for manufacturing the same.

2. Description of Related Art

In recent years, demands for solid-state imaging devices to be mounted in digital still cameras and digital video cameras have increased. Moreover, models of portable terminal devices represented by mobile phones, which have camera functions, have been increased. The demands for solid-state imaging devices have been expanded for imaging devices in such portable terminal devices. Furthermore, in order to obtain an image with high quality, the number of pixels in a solid-state imaging device has been increased year by year. In addition, in accordance with the request for decreased power consumption of digital still cameras, digital video cameras and portable terminal devices, demands for solid-state imaging devices with lower power consumption also have increased.

A configuration of a conventional solid-state imaging device will be described with reference to FIGS. 6 to 8. Firstly, the configuration of the solid-state imaging device will be described schematically. FIG. 6 is a plan view schematically showing a configuration of a conventional CCD solid-state imaging device. As shown in FIG. 6, the CCD solid-state imaging device includes a semiconductor substrate 101. The semiconductor substrate 101 is provided with: a plurality of photodetectors 102 that are arranged in a two-dimensional matrix; vertical transfer portions (vertical CCDs) 103 that are disposed along respective alignments (columns) of the photodetectors 102 in a vertical direction; and a horizontal transfer portion (horizontal CCD) 104 that is disposed adjacent to a final row (row at the bottom end in FIG. 6) of the photodetectors 102. The photodetector 102 is constituted of a photodiode, in which an electric charge dependent on an intensity of received light is accumulated. Moreover, one pixel 108 shown by a square in broken line includes: one of the photodetectors 102; and a part of the vertical CCD 103 adjacent to this photodetector 102.

In FIG. 6, the electric charge accumulated in the photodetector 102 is read out by the vertical CCD 103, and is transferred by the vertical CCD 103 in the vertical direction (toward a lower side in FIG. 6) as shown by an arrow. The electric charge that is transferred to the bottom end of the vertical CCD 103 is conveyed to the horizontal CCD 104, and is transferred by the horizontal CCD 104 in the horizontal direction (toward a left side in FIG.6). A voltage corresponding to the electric charge that is transferred to the left end of the horizontal CCD 104 is amplified by the amplifier 105, and subsequently is output to the outside.

Moreover, as shown in FIG. 6, a side of the horizontal CCD 104. opposing a side that is adjacent to the vertical CCD 103 (lower side in FIG. 6) is in contact with a drain region 107 via a barrier region 106 (or example, see JP 2(1990)-205359 A). The barrier region 106 is a potential barrier, and allows only an excess electric charge of the horizontal CCD 104 to pass through. Thus, a surplus of the electric charge that is transferred from the vertical CCD 103 to the horizontal CCD 104 (excess electric charge) passes through the barrier region 106, and is drained to the drain region 107.

Next, specific configurations of the vertical CCD 103, the horizontal CCD 104 and the drain region 107 will be described with reference to FIGS. 7 and 8.

FIG. 7 is an enlarged plan view showing a part of the conventional CCD solid-state imaging device shown in FIG. 6. FIG. 8 is a plan view more specifically showing a configuration of the part of the conventional CCD solid-state imaging device shown in FIG. 7.

As shown in FIG. 7, each of the vertical CCD 103 and the horizontal CCD 104 includes: a channel region 109 that is a transfer path for the electric charge of each CCD; and a two-layered transfer electrode. Moreover, in FIG. 7, a first-layer transfer electrode is illustrated with hatching. Specifically, the vertical CCD 103 includes: a portion 109a of the channel region 109 that extends in a vertical direction; a first-layer vertical transfer electrode 112; and a second-layer vertical transfer electrode 113. The vertical CCD 103 is four-phase driven. Moreover, the horizontal CCD 104 includes: a portion 109b of the channel region 109 that extends in a horizontal direction; a first-layer horizontal transfer electrode 110; and a second-layer horizontal transfer electrode 111. The horizontal CCD 104 is two-phase driven.

Moreover, the channel region 109 is formed on a p-type well that is formed on the semiconductor substrate 101. Furthermore, the channel region 109, the barrier region 106 and the drain region 107 are n-type diffusion layers, on which a gate insulation film is formed. Moreover, on a side of the drain region 107 opposing the channel region 109 side, an insulation layer having a thickness larger than a thickness of the gate insulation film is formed. This insulation layer is generally called a LOCOS (Local Oxidation of Silicon) oxide film. This LOCOS oxide film is an isolation film that functions with respect to a peripheral circuit (not illustrated) such as a protective circuit, and actually is formed so as to surround a whole major portion including: the plurality of the photodetectors 102; the vertical CCD 103; the horizontal CCD 104; the barrier region 106; and the drain region 107.

Moreover, as shown in FIGS. 7 and 8, the horizontal transfer electrodes 110 and 111 are formed so as to overlap with the barrier region 106, the drain region 107 and the LOCOS oxide film along the vertical direction.

As shown in FIG. 8, a control voltage is applied to the horizontal transfer electrodes 110 and 111 via contact holes CH, and a H1 bus line 112 and a H2 bus line 113 that are provided on the contact holes CH. That is, ends of the horizontal transfer electrodes 110 and 111 are extended so as to overlap with the H1 bus line 112 or the H2 bus line 113, and a pair of the contact holes CH are formed on a part where the horizontal transfer electrodes 110 and 111 overlap with the H1 bus line 112 or the H2 bus line 113. In the illustrated example, a pair of the horizontal transfer electrodes 110 and 111 to be connected to the H1 bus line 112 and a pair of the horizontal transfer electrodes 110 and 111 to be connected to the H2 bus line 113 are arranged alternately. And, for the convenience of layout, the ends of the pair of the horizontal transfer electrodes 110 and 111 to be connected to the H1 bus line 112 are extended so as to have a length more than a length of the pair of the horizontal transfer electrodes 110 and 111 to be connected to the H2 bus line 113.

Generally, an aluminum wiring is used as the bus line, and a first-layer polysilicon is used as the horizontal transfer electrode 110, and a second-layer polysilicon is used as the horizontal transfer electrode 111.

In the conventional solid-state imaging device having the above-described configuration, if the number of the pixels is increased, the number of the horizontal transfer electrodes per unit length is increased, and thus the width of each of the horizontal transfer electrodes is decreased so as to increase electric resistance, thereby increasing the amount of delay of a driving pulse. Therefore, a measure for controlling the delay of the driving pulse is required. It is thought that the increase of the electric resistance of the horizontal transfer electrodes can be controlled to some extent, by, for example, increasing an impurity density of the polysilicon forming the horizontal transfer electrodes 110 and 111, that is, increasing a doping amount of phosphorus in the polysilicon forming the horizontal transfer electrodes 110 and 111, or increasing film thicknesses thereof However, the increase of the film thicknesses may cause a problem in processing such as etching and a problem of degrading the light condensing efficiency due to an increase in height of the device (thickness dimension).

Moreover, the increase of the doping amount of phosphorus is limited, and the doping amount of phosphorus cannot be increased beyond a limit of a solid solubility. Furthermore, insulation is provided to the horizontal transfer electrodes 110 and 111 by an oxide film that is obtained by oxidizing the horizontal transfer electrode 110 by heat, however, a film thickness of the oxide film is increased when the doping amount of phosphorus is increased, and the transfer efficiency is degraded by an increase of a distance between the transfer electrodes. Moreover, if an oxidation amount is equivalent to the conventional oxidation amount, a concentration of phosphorus in the oxide film is increased, which may lead to a decrease of a dielectric breakdown strength (dielectric withstand voltage). Therefore, there is a limit to controlling the delay of the driving pulse by increasing the impurity density of the polysilicon forming the horizontal transfer electrodes 110 and 111.

### SUMMARY OF THE INVENTION

Therefore, with the foregoing in mind, it is an object of the present invention to provide a solid-state imaging device that can suppress an electric power loss in a horizontal transfer portion and can achieve both an increase in the number of pixels and a decrease in power consumption, and a method for manufacturing the same.

In order to attain the above-mentioned object, the solid-state imaging device of the present invention includes: a plurality of photodetectors that are arranged in a two-dimensional matrix; a plurality of vertical transfer portions that transfer, in a vertical direction, signal electric charges that respectively are read out from the plurality of the photodetectors; a horizontal transfer portion that receives the signal electric charges respectively transferred by the plurality of the vertical transfer portions, and transfers the signal electric charges in a horizontal direction; a barrier region that is adjacent to the horizontal transfer portion, and allows an excess electric charge in the horizontal transfer portion to pass through; a drain region that is adjacent to the barrier region and drains the excess electric charge which has passed through the barrier region; and a bus line that is disposed in parallel with the drain region, and applies a control voltage to an electrode of the horizontal transfer portion, wherein the bus line and the electrode of the horizontal transfer portion are connected via a connection pattern that is disposed between the bus line and the drain region.

Moreover, the method for manufacturing a solid-state imaging device according to the present invention is a method for manufacturing the solid-state imaging device with the above-described configuration, wherein a connection pattern of the bus line and the electrode of the horizontal transfer portion is formed at the same time when a light shielding region of a pixel portion is formed.

These and other advantages of the present invention will become apparent to those skilled in the art upon reading and understanding the following detailed description with reference to the accompanying figures.

### BRIEF DESCRIPTION OF THE DRAWINGS

FIG. 1 is a plan view schematically showing a configuration of a solid-state imaging device according to Embodiment 1 of the present invention.

FIG. 2 is a plan view showing a plane constitution of the solid-state imaging device shown in FIG. 1.

FIG. 3 is a view showing a cross section taken along line a-a′ in FIG. 2.

FIG. 4 is a plan view showing a plane constitution of the solid-state imaging device according to Embodiment 1 of the present invention.

FIG. 5 is a plan view showing a plane constitution of a solid-state imaging device according to Embodiment 2 of the present invention.

FIG. 6 is a plan view schematically showing a configuration of a conventional CCD solid-state imaging device.

FIG. 7 is an enlarged plan view showing a part of the conventional CCD solid-state imaging device shown in FIG. 6.

FIG. 8 is a plan view showing a planar construction of the CCD solid-state imaging device shown in FIG. 7.

### DETAILED DESCRIPTION OF THE INVENTION

According to a preferred embodiment of the solid-state imaging device of the present invention, as the bus lines, a first bus line that has a longer distance from the drain region and a second bus line that has a shorter distance from the drain region are provided, and the connection pattern that connects the first bus line to the electrode of the horizontal transfer portion is disposed so as to cross the second bus line. This is suitable as a configuration of a solid-state imaging device having a horizontal transfer portion that is two-phase driven.

According to another preferred embodiment of the solid-state imaging device of the present invention, the connection pattern is made of a material that has a lower electric resistance than the electric resistance of the material of the electrode of the horizontal transfer portion. Thereby, the electric power loss of the horizontal transfer portion including a bus line can be suppressed.

According to still another preferred embodiment of the solid-state imaging device of the present invention, the material of the connection pattern is a metal or a metal compound that has a high melting point.

According to still another preferred embodiment of the solid-state imaging device of the present invention, the connection pattern is formed beneath the bus line.

According to still another preferred embodiment of the solid-state imaging device of the present invention, the connection pattern is formed to have a thickness that is equivalent to or smaller than a thickness of the electrode of the horizontal transfer portion.

According to still another preferred embodiment of the solid-state imaging device of the present invention, each unit of the horizontal transfer portion is provided with: a drain region connecting portion for applying a voltage to the drain region; and a drain contact region that is a portion for connecting the drain region connecting portion to a power supply line, and the drain contact region is formed so as to be positioned between the electrode of the horizontal transfer portion and the bus line.

According to such a configuration, an area of a part of the drain region that overlaps with the horizontal transfer electrode can be decreased. Thus, due to a decrease of a load capacity, a further decrease in the power consumption can be attained. According to still another preferred embodiment of the solid-state imaging device of the present invention, a contact hole of the horizontal transfer electrode and the drain contact region are arranged in a zigzag alignment in a plan view.

According to such a configuration, a fine design rule is not required, thereby suppressing an increase in cost for a diffusing step.

According to still another preferred embodiment of the solid-state imaging device of the present invention, the drain region connecting portion is disposed in a substantially linear manner, along the vertical transfer portion and a horizontal transfer electrode that receives a signal electric charge from the vertical transfer portion.

According to such a configuration, a path for excess charges that are drained from the vertical transfer portion to the drain region through the horizontal transfer portion can be configured to have the shortest distance, which contributes to increasing the degree of freedom of the driving timing.

According to still another preferred embodiment of the solid-state imaging device of the present invention, the power supply line that is connected to the drain region connecting portion in the drain contact region functions also as a light shielding film of the horizontal transfer portion.

According to such a configuration, the number of necessary wirings can be decreased, and an extended portion of the horizontal transfer electrode can be shortened, which can achieve a decrease in chip size and suppress an increase in power consumption.

Moreover, according to a preferred embodiment of the method for manufacturing a solid-state imaging device of the present invention, the bus line is formed at the same time when a wiring of a peripheral circuit is formed.

According to such a configuration, at the same time when the bus line is formed, for example, a source-drain wiring or the like of a MOS transistor that constitutes a peripheral circuit such as a protective circuit can be formed. Thereby, an increase in the number of steps required for manufacturing a solid-state imaging device can be suppressed, which accordingly can suppress an increase of the cost for manufacturing the solid-state imaging device.

According to the solid-state imaging device of the present invention, the bus line and the horizontal transfer electrode can be connected in a connection pattern with low resistance, and the increase of the electric power loss in the horizontal transfer portion including the bus line can be suppressed. Therefore, the solid-state imaging device of the present invention can maintain a horizontal transferring speed and can decrease power consumption, while satisfying the demand for increasing the number of pixels.

Moreover, according to the method for manufacturing a solid-state imaging device of the present invention, the above-described connection pattern is formed at the same time when a light shielding region of a pixel portion is formed, whereby a solid-state imaging device that can achieve both of the increase in the number of pixels and the decrease in power consumption can be manufactured, without increasing any manufacturing processes.

(Embodiment 1)

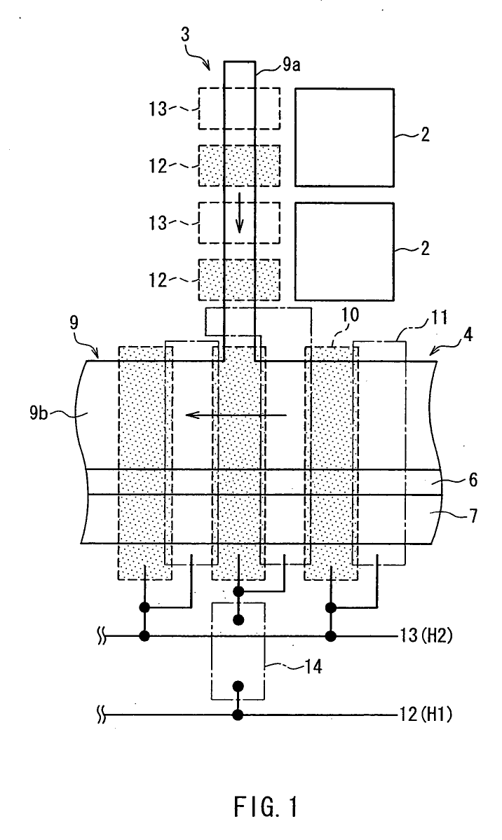

FIG. 1 is a plan view schematically showing a configuration of a solid-state imaging device according to Embodiment 1 of the present invention.

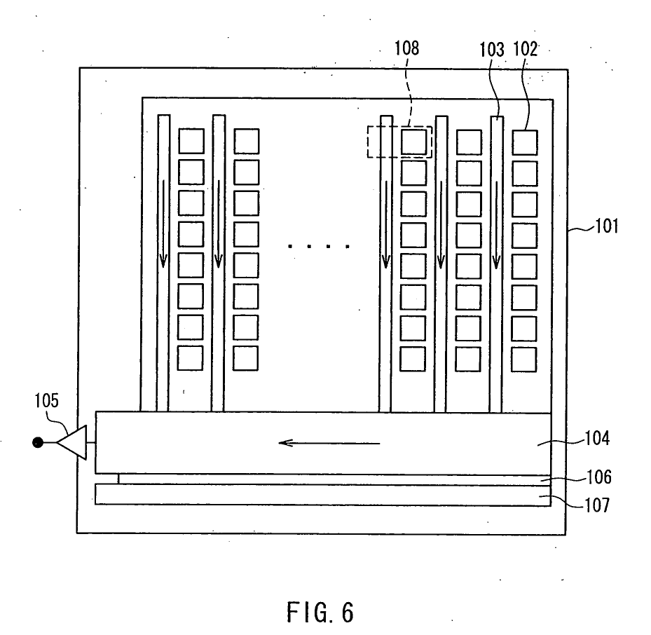

As shown in FIG. 1, the solid-state imaging device according to Embodiment 1 is a CCD solid-state imaging device that is configured on a semiconductor substrate. Similarly to the conventional example shown in FIGS. 6 to 8 in Description of Related Art, the semiconductor substrate (101 in FIG. 6) is provided with: a plurality of photodetectors 2 that are arranged in a two-dimensional matrix; and vertical transfer portions (vertical CCDs) 3 that are disposed along respective alignments (columns) of the alignment of the photodetectors 2 in a vertical direction. Moreover, a horizontal transfer portion (horizontal CCD) 4 is provided adjacent to a final row of the vertical transfer portions 3.

The photodetector 2 is composed of a photodiode, in which an electric charge dependent on an intensity of received light is accumulated. Moreover, each of the vertical CCD 3 and the horizontal CCD 4 is a CCD that is provided with a channel region and a transfer electrode. The vertical CCD 3 transfers a signal electric charge that is read out from the photodetector 2 in the vertical direction, and the horizontal CCD 4 receives the signal electric charge that is transferred by the vertical CCD 3, and transfers it in the horizontal direction.

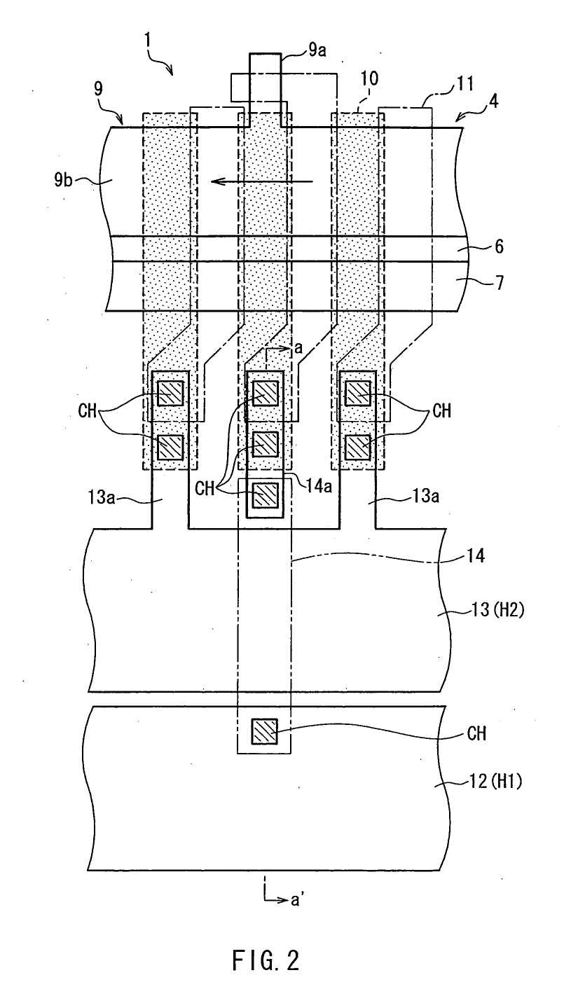

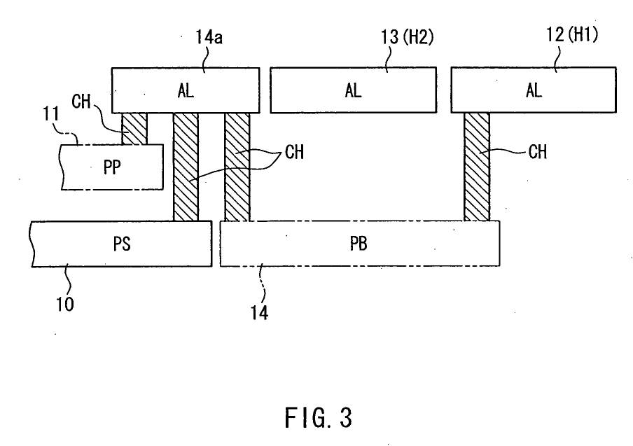

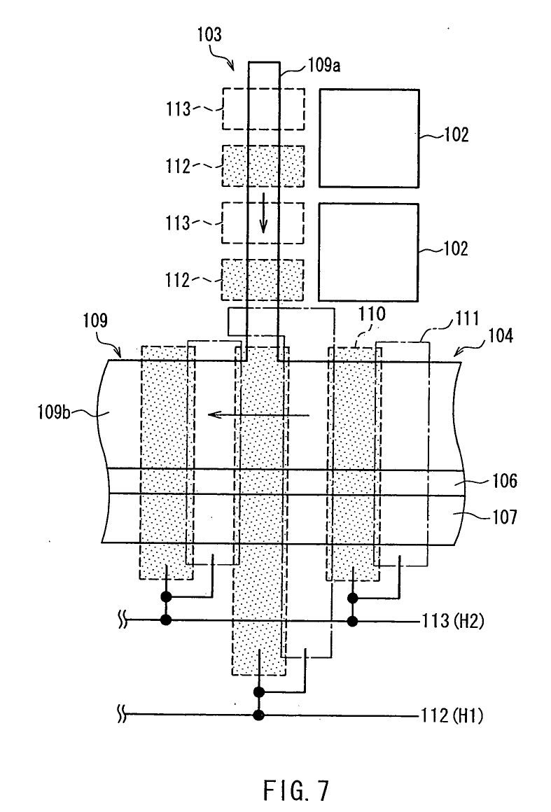

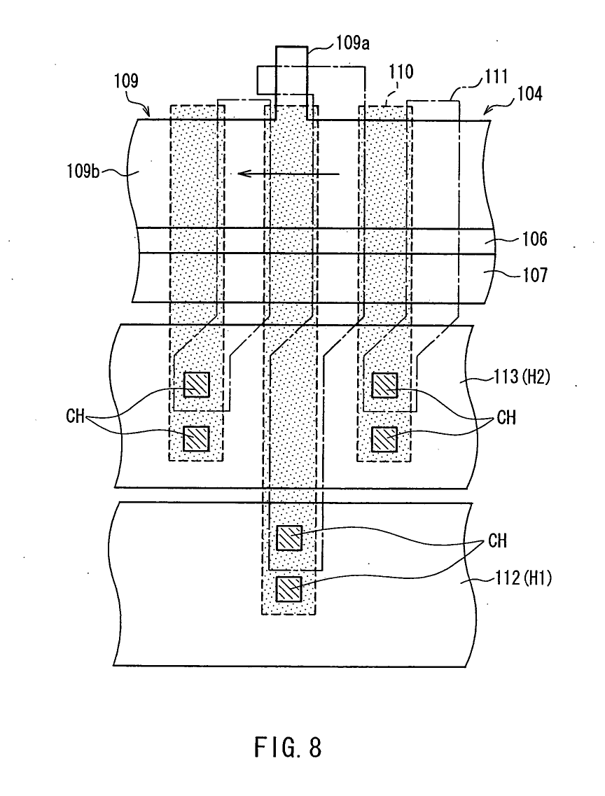

Moreover, in FIGS. 1 to 3, the vertical CCD 3 and the horizontal CCD 4 are illustrated partly. FIG. 1 corresponds to FIG. 7 in the conventional example, and FIG. 2 corresponds to FIG. 8 in the conventional example. A cross section shown in FIG. 3 is a cross section taken along line a-a′ in FIG. 2, which illustrates only a line that appears on the cross section.

As shown in FIG. 1, each of the vertical CCD 3 and the horizontal CCD 4 includes: a channel region 9 that is a transfer path for electric charges; and a two-layered transfer electrode. More specifically, the vertical CCD 3 includes: a portion 9a of the channel region 9 that extends in a vertical direction; a first-layer vertical transfer electrode 12; and a second-layer vertical transfer electrode 13. Moreover, the horizontal CCD 4 includes: a portion 9b of the channel region 9 that extends in a horizontal direction; a first-layer horizontal transfer electrode 10; and a second-layer horizontal transfer electrode 11. The vertical CCD 3 is four-phase driven, and the horizontal CCD 4 is two-phase driven. Moreover, in FIG. 1, the first-layer transfer electrode is illustrated with hatching so as to be distinguished from the second-layer transfer electrode.

The channel region 9 is formed on a p-type well that is formed on the semiconductor substrate. Moreover, the channel region 9, the barrier region 6 and the drain region 7 are n-type diffusion layers, on which a gate insulation film is formed. Furthermore, on a side of the drain region 7 opposing the channel region 9 side, an insulation layer having a thickness larger than a thickness of the gate insulation film is formed. This insulation layer is called a LOCOS oxide film, as described above. This LOCOS oxide film is an isolation film that functions with respect to a peripheral circuit (not illustrated) such as a protective circuit, and actually is formed so as to surround a whole major portion including: the plurality of the photodetectors 2; the vertical CCD 3; the horizontal CCD 4; the barrier region 6; and the drain region 7.

Moreover, as shown in FIGS. 1 and 2, the horizontal transfer electrodes 10 and 11 are formed so as to overlap with the barrier region 6, the drain region 7 and the LOCOS oxide film along the vertical direction. Moreover, as shown in FIGS. 1 to 3, a control voltage is applied to the horizontal transfer electrodes 10 and 11 via contact holes CH, a connection pattern (short wiring pattern) 14 with low resistance, and a Hi bus line (first bus line) 12 and a H2 bus line (second bus line) 13 that are provided on the connection pattern 14. In the illustrated example, the H2 bus line 13 is provided with a protruding portion 13a that protrudes toward the horizontal transfer electrode 10 (upward in FIG. 2), and is connected with the horizontal transfer electrodes 10 and 11 via the contact holes CH at tip portions thereof Moreover, the H1 bus line 12 and the horizontal transfer electrodes 10 and 11 are connected via the connection pattern 14, an auxiliary connection pattern 14a and a plurality of the contact holes CH. According to the configuration of Embodiment 1, as shown in FIGS. 1 and 2, the horizontal transfer electrodes 10 and 11 to be connected to the H1 bus line 12 may have shapes (lengths) that respectively are same as those of the horizontal transfer electrodes 10 and 11 to be connected to the H2 bus line 12.

The bus lines 12 and 13 are made of an aluminum film, and the connection pattern 14 is made of a tungsten film. The auxiliary connection pattern 14a is made of the aluminum film that is the same as the material of the bus lines 12 and 13. Moreover, the horizontal transfer electrode 10 is made of a first-layer polysilicon. Furthermore, the horizontal transfer electrode 11 is made of a second-layer polysilicon. Thus, the connection pattern 14 and the auxiliary connection pattern 14a respectively are made of materials that have lower electric resistance than the materials of the horizontal transfer electrodes 10 and 11. Herein, the electric resistance of tungsten is no more than 1/100 to 1/10 of electric resistance of polysilicon. Moreover, the light shielding film of the photodetector, which is not illustrated in FIG. 3, is made of the tungsten film that is the same as the material of the connection pattern 14.

Also in the present embodiment, similarly to the conventional example shown in FIGS. 6 to 8 in Description of Related Art, each of the barrier region 6 and the drain region 7 is shaped to be elongated in the horizontal direction. Moreover, the barrier region 6 and the drain region 7 are arranged in this order so as to increase a distance from the horizontal CCD 4, on a side of the horizontal CCD 4 opposing a side thereof to which the vertical CCD 3 is in contact. Furthermore, also in the present embodiment, on the periphery of a region where the photodetector 2, the vertical CCD 3, the horizontal CCD 4, the barrier region 6 and the drain region 7 are provided, a transistor element (not illustrated in FIG. 1) that constitutes the peripheral circuit is formed. Moreover, the semiconductor substrate is a n-type silicon substrate, and a p-type well (not illustrated in FIG. 1) is formed -on the semiconductor substrate. The channel region 9 and 9a, the barrier region 6 and the drain region 7 are n-type diffusion layers, which are formed in the region where the p-type well is provided. Furthermore, a gate insulation film is formed on these.

As mentioned above, in the solid-state imaging device of the present invention, the contact holes CH that connect the bus lines 12 and 13 to the horizontal transfer electrodes 10 and 11 are formed in positions that do not overlap with the bus lines 12 and 13, more specifically, between the bus lines 12 and 13 and the drain region 7. And, the H1 bus line 12 having a longer distance from the drain region 7 is connected to the horizontal transfer electrodes 10 and 11 via the connection pattern 14 (and the auxiliary connection pattern 14a) that is disposed so as to cross the H2 bus line 13 having a shorter distance from the drain region 7.

According to such a configuration, a dimensional ratio of the contact holes CH that occupy the bus lines 12 and 13 in their width direction is less than that of the conventional example shown in FIG. 8, thereby suppressing the increase in electric power loss in the horizontal transfer portion including the bus lines. If the solid-state imaging device according to the present embodiment is used in a digital still camera or the like, it can achieve both of the increase in the number of pixels and the decrease in power consumption.

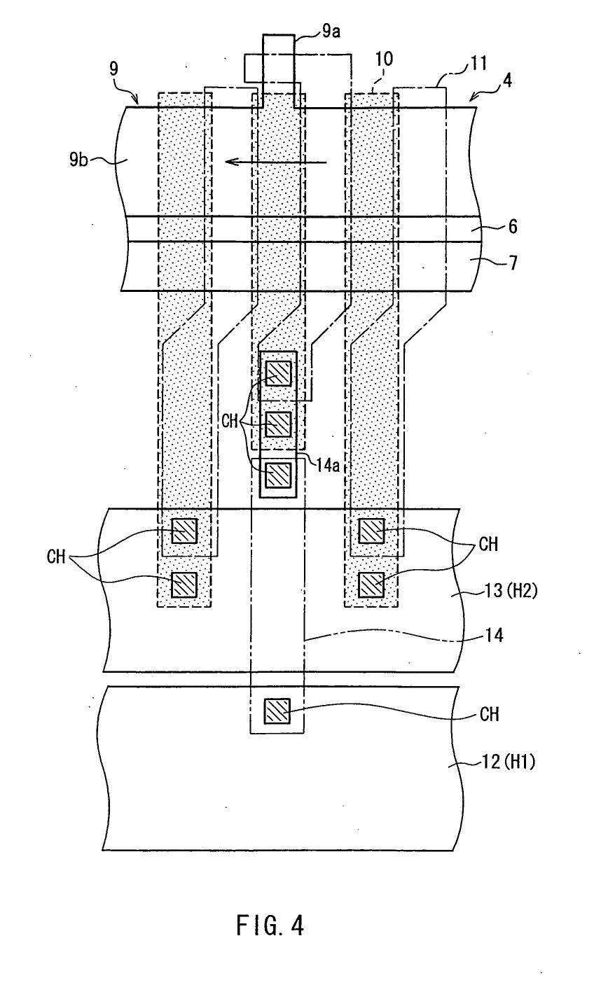

In the case of using a low-cost manufacturing apparatus that has a limited microprocessing capability while processing the contact holes CH so as to save the cost, a layout shown in FIG. 4 preferably is adopted. More specifically, the H2 bus line 13 is not provided with the protruding portion 13a for connecting with the horizontal transfer electrode shown in FIG. 2, but is provided with the contact holes CH that are disposed in the width of the H2 bus line 13. Herein, unlike the conventional example shown in FIG. 8, the contact holes CH are disposed so as to be positioned near an edge of the H2 bus line 13 in its width direction as much as possible. Moreover, the H1 bus line 12 is provided with a contact for connecting to the connection pattern 14 on an edge thereof in its width direction, similarly to the configuration shown in FIG. 2. Such a layout can suppress the increase in electric power loss in the horizontal transfer portion including the bus lines.

(Embodiment 2)

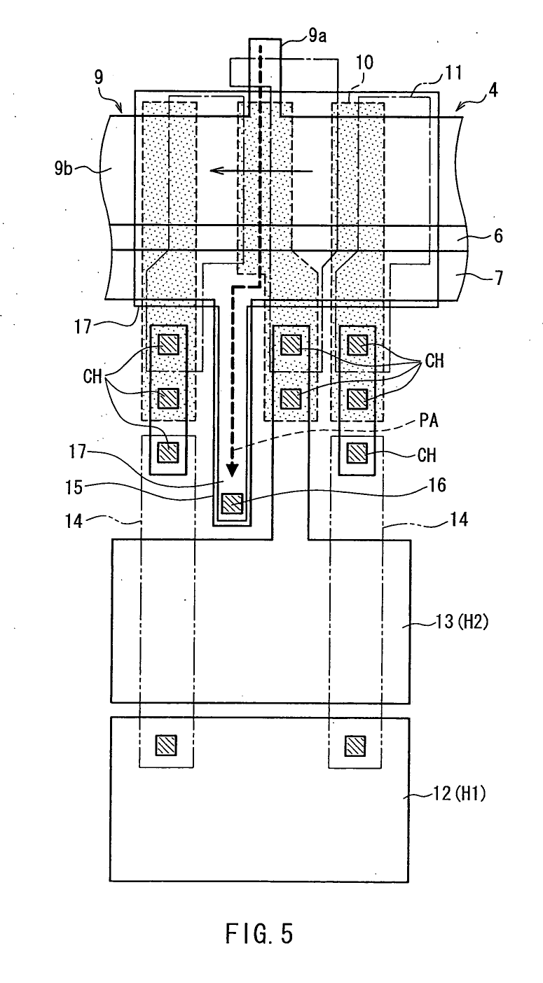

FIG. 5 is a plan view schematically showing a configuration of a solid-state imaging device according to Embodiment 2 of the present invention.

As shown in FIG. 5, in the solid-state imaging device according to the present embodiment, each unit of the horizontal CCD 4 is provided with: a drain region connecting portion 15 for applying a voltage to the drain region 7; and a drain contact region 16 that is a portion for connecting this drain region connecting portion 15 to a power supply line.

Such an arrangement can suppress, in the drain region 7, an increase of an impurity density that is accompanied by degradation of a withstand voltage due to a decrease in resistance value which determines a drain capability, and an increase of a drain area that is accompanied by an increase in load capacity. As a result, an area of a thin film region of an insulation film that is covered with the horizontal transfer electrodes 10 and 11 is decreased to be less than that of the conventional solid-state imaging device, which can lead to the further decrease in power consumption by decreasing the load capacity. Moreover, as shown in FIG. 5, the drain contact region 16 is formed so as to be positioned between: the horizontal transfer electrodes 10 and 11; and the bus lines H1 and H2, and the contact holes CH of the horizontal transfer electrodes 10 and 11 and the drain contact region 16 are positioned in a zigzag alignment, whereby a fine design rule is not required to be used, thus suppressing the increase of the cost in the diffusing step.

The drain region connecting portion 15 is disposed in a substantially linear manner, along the vertical transfer portion (the portion 9a in the channel region) and the horizontal transfer electrode 10 that receives a signal electric charge from the vertical transfer portion. Thereby, a path for excess charges that are drained from the vertical transfer portion (the portion 9a in the channel region) to the drain region 7 through the horizontal transfer electrode 10 can be configured to have the shortest distance, as shown by an arrow PA. As a result, the degree of freedom of a driving timing can be increased.

Moreover, an aluminum wiring 17 for applying a voltage to the drain contact region 16 functions also as a light shielding film of the horizontal CCD 4. Thereby, the necessary wirings can be decreased, and the extended portions of the horizontal transfer electrodes 10 and 11 can be shortened, which can decrease the chip size and suppress the increase in power consumption.

The embodiments of the present invention were described above, but the present invention may be carried out by modifying these embodiments as appropriate. Moreover, in the above-described Embodiments 1 and 2, the solid-state imaging device of which the transfer type is an interline transfer (IT) type was exemplified for the explanation, but the present invention also can be applied to a frame transfer (FT) solid-state imaging device and a frame interline transfer (FIT) solid-state imaging device.

The present invention can be applied to a solid-state imaging device that is used in digital still cameras, digital video cameras, portable terminal devices and the like, and can achieve both of the increase in the number of pixels and the decrease in power consumption.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A solid-state imaging device comprising:
a plurality of photodetectors that are arranged in a two-dimensional matrix;
a plurality of vertical transfer portions that transfer, in a vertical direction, signal electric charges that respectively are read out from the plurality of the photodetectors;
a horizontal transfer portion that receives the signal electric charges respectively transferred by the plurality of the vertical transfer portions, and transfers the signal electric charges in a horizontal direction;
a barrier region that is adjacent to the horizontal transfer portion, and allows an excess electric charge in the horizontal transfer portion to pass through;
a drain region that is adjacent to the barrier region and drains the excess electric charge which has passed through the barrier region; and
a bus line that is disposed in parallel with the drain region, and applies a control voltage to an electrode of the horizontal transfer portion,
wherein the bus line and the electrode of the horizontal transfer portion are connected via a connection pattern that is disposed between the bus line and the drain region.

2. The solid-state imaging device according to claim 1, wherein the bus line comprises:
a first bus line that has a longer distance from the drain region; and
a second bus line that has a shorter distance from the drain region, and
the connection pattern that connects the first bus line to the electrode of the horizontal transfer portion is disposed so as to cross the second bus line.

3. The solid-state imaging device according to claim 1, wherein the connection pattern is made of a material that has a lower electric resistance than an electric resistance of a material of the electrode of the horizontal transfer portion.

4. The solid-state imaging device according to claim 3, wherein the material of the connection pattern is a metal or a metal compound that has a high melting point.

5. The solid-state imaging device according to claim 1, wherein the connection pattern is formed beneath the bus line.

6. The solid-state imaging device according to claim 1, wherein the connection pattern is formed to have a thickness that is equivalent to or smaller than a thickness of the electrode of the horizontal transfer portion.

7. The solid-state imaging device according to claim 1, wherein each unit of the horizontal transfer portion is provided with:
a drain region connecting portion for applying a voltage to the drain region; and
a drain contact region that is a portion for connecting the drain region connecting portion to a power supply line, and
the drain contact region is formed so as to be positioned between the electrode of the horizontal transfer portion and the bus line.

8. The solid-state imaging device according to claim 7, wherein a contact hole of the horizontal transfer electrode and the drain contact region are arranged in a zigzag alignment in a plan view.

9. The solid-state imaging device according to claim 7, wherein the drain region connecting portion is disposed in a substantially linear manner, along the vertical transfer portion and a horizontal transfer electrode that receives a signal electric charge from the vertical transfer portion.

10. The solid-state imaging device according to claim 7, wherein the power supply line that is connected to the drain region connecting portion in the drain contact region functions also as a light shielding film of the horizontal transfer portion.

11. A method for manufacturing the solid-state imaging device according to claim 1,
wherein a connection pattern of the bus line and the electrode of the horizontal transfer portion is formed at the same time when a light shielding region of a pixel portion is formed.

12. The method for manufacturing a solid-state imaging device according to claim 11, wherein the bus line is formed at the same time when a wiring of a peripheral circuit is formed.
